(19) United States
(12) Patent Application Publication
(10) Pub. No.: US 2013/0105422 A1
(43) Pub. Date: May 2, 2013

(54) FIXING DEVICE FOR DATA STORAGE DEVICE

(71) Applicant: HAI-QING ZHOU, Shenzhen City (CN)

(72) Inventor: HAI-QING ZHOU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/407,781

(22) Filed: Feb. 29, 2012

(30) Foreign Application Priority Data
Oct. 26, 2011 (CN) 201110329526.0

(51) Int. Cl. H05K 7/18

(52) U.S. Cl. 211/26

(57) ABSTRACT

A fixing device for fixing a data storage device includes a rack, a fixing member, and a resilient member. The rack includes a bottom plate and two tabs protruding from the bottom plate. Two first pins respectively extend from the tabs to engage in two corresponding holes defined in a first sidewall of the data storage device. The fixing member is slidably mounted on the bottom plate along a direction perpendicular to the tabs. A second pin protrudes from the fixing member to detachably engage in a locking hole defined in a second sidewall of the data storage device. The resilient member is resiliently sandwiched between the rack and the fixing member, to bias the fixing member to move towards the data storage device, thereby making the second pin engage in the locking hole.

### BACKGROUND

1. Technical Field

The present disclosure relates to means of affixation for data storage devices.

2. Description of Related Art

An electronic device, such as a computer, may be equipped with data storage devices, such as an optical disk drive. Mounting the optical disk drive to the electronic device with screws is inefficient and requires the use of a tool, such as a screwdriver, which is inconvenient.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an exemplary embodiment of a fixing device, together with an optical disk drive (ODD), wherein the fixing device includes a fixing member.

FIGS. 2-4 are exploded, isometric views of the fixing device and the ODD of FIG. 1, but viewed from different perspectives.

FIG. 5 is a sectional view taken along line V-V of FIG. 1.

FIG. 6 is similar to FIG. 5, but shows another state.

FIG. 7 is an enlarged view of the fixing member of FIG. 3.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

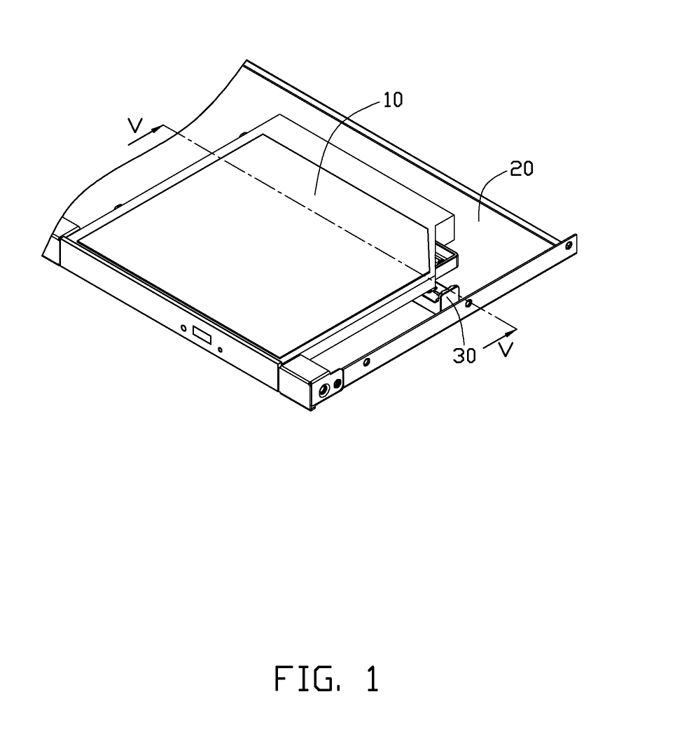

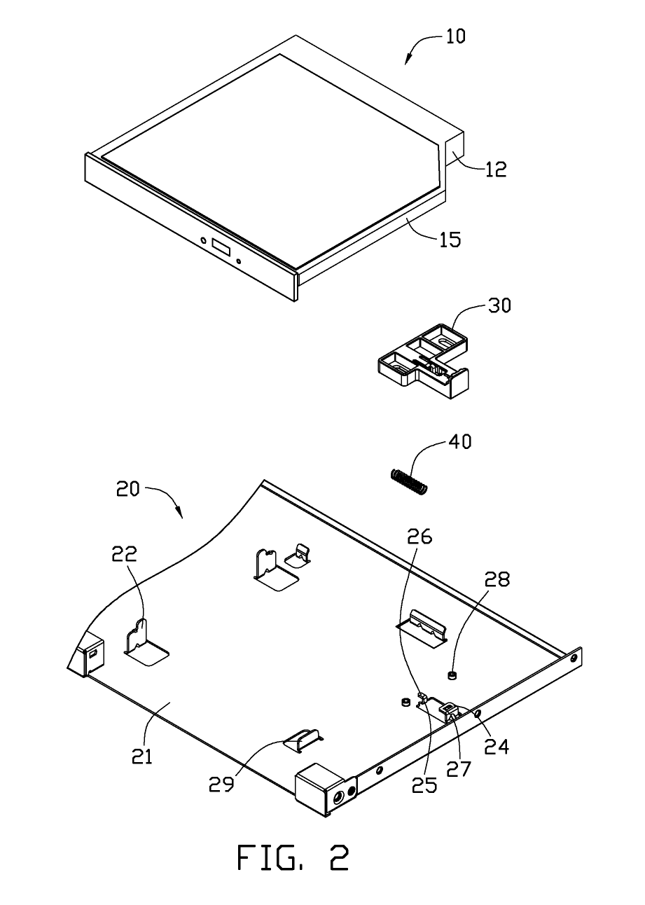

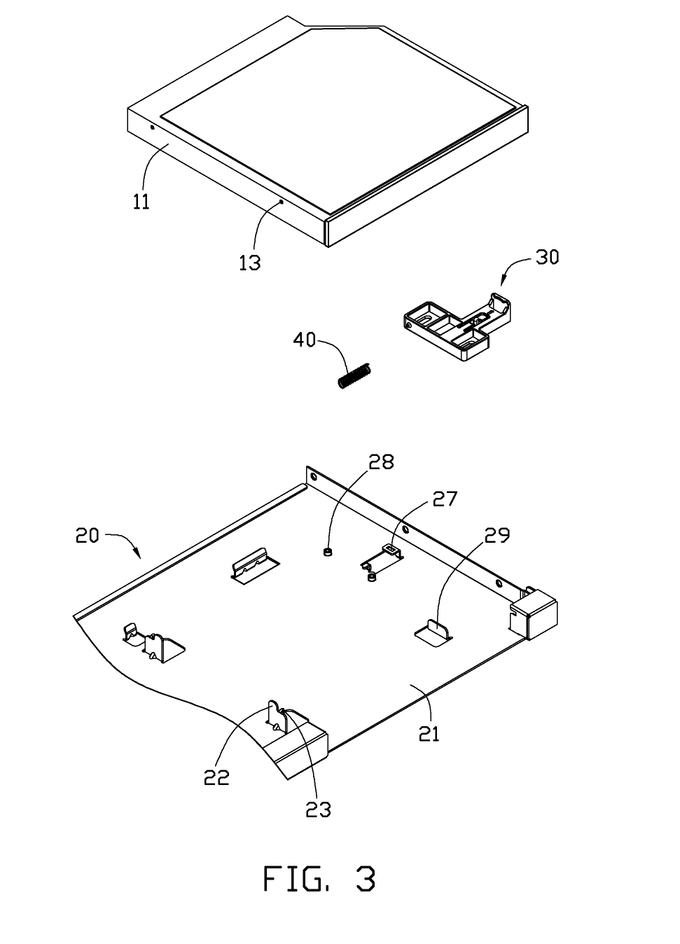

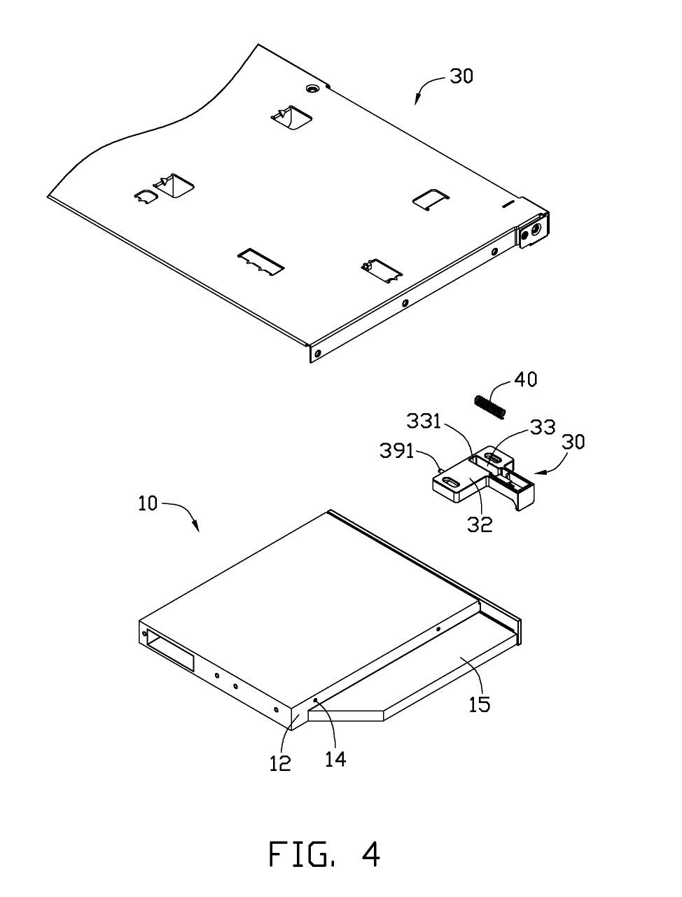

Referring to FIGS. 1-4, an exemplary embodiment of a fixing device for fixing a data storage device, such as an optical disk drive (ODD) 10, includes a rack 20, a fixing member 30, and a resilient member 40. In the embodiment, the resilient member 40 is a spring.

The ODD 10 includes a first sidewall 11 and a second sidewall 12 opposite to the first sidewall 11. Two spaced holes 13 are defined in the first sidewall 11. A plate 15 perpendicularly extends from an upper portion of the second sidewall 12. A locking hole 14 is defined in the second sidewall 12, below the plate 15.

The rack 20 includes a bottom plate 21. Two first tabs 22 protrude from the bottom plate 21, in alignment with each other. A second tab 29 protrudes up from the bottom plate 21, opposite to the first tabs 22. A pin 23 protrudes from each first tab 22 toward the second tab 29. An L-shaped hooking portion 24 protrudes from the bottom plate 21, adjacent to the second tab 29. The hooking portion 24 perpendicularly extends from the bottom plate 21, and then extends toward the first tabs 22. A hooking slot 27 is defined in the top of the hooking portion 24. A stopping tab 25 protrudes up from the bottom plate 21, aligning with the hooking portion 24 and between the hooking portion 24 and the second tab 29. A pole 26 extends from the top of the stopping tab 25, away from the hooking portion 24. Two limitation protrusions 28 protrude from the bottom plate 21, at opposite sides of the stopping tab 25.

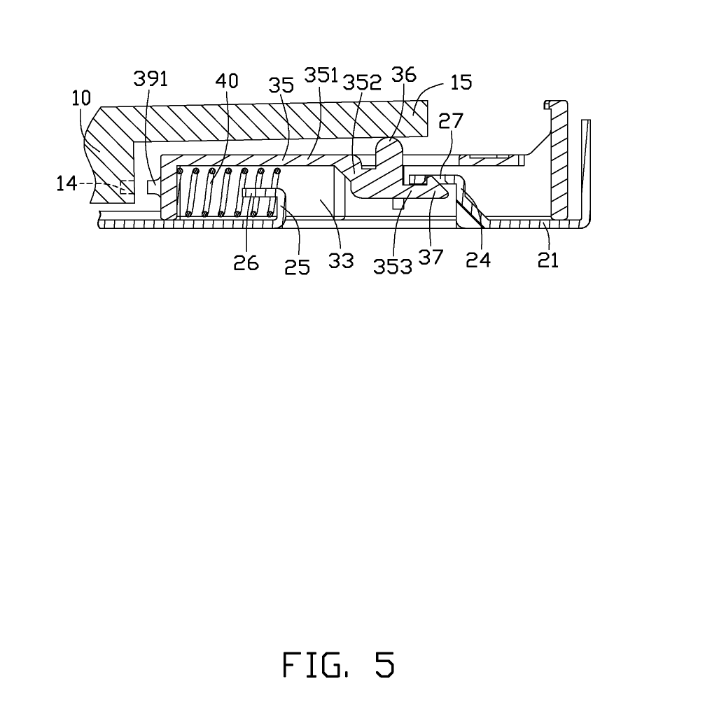

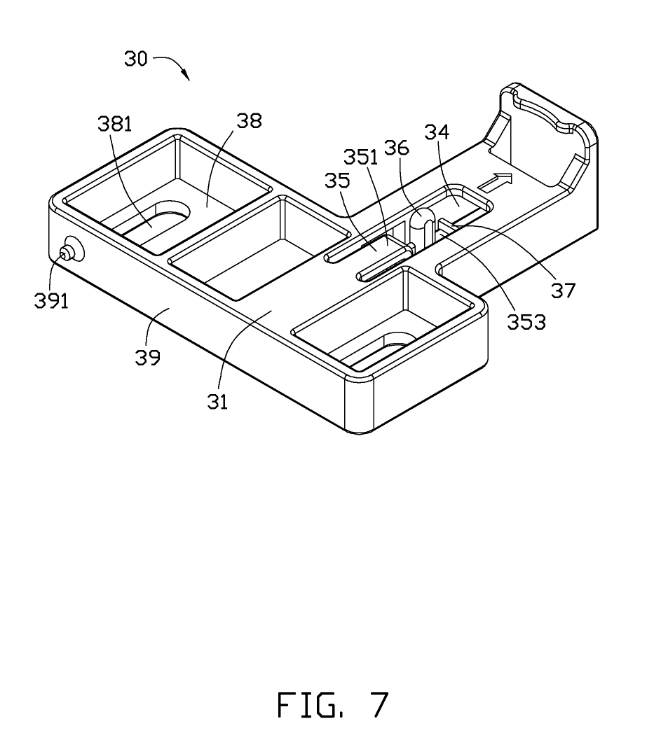

Referring to FIGS. 5 and 7, the fixing member 30 includes a top wall 31, a bottom wall 32 opposite to the top wall 31, and a sidewall 39 perpendicularly connected between first sides of the top wall 31 and the bottom wall 32. A recess 33 is defined in the bottom wall 32, extending along a direction perpendicular to the sidewall 39. The recess 33 includes an end wall 331 adjacent to the sidewall 39. An opening 34 is defined in the top wall 31, above the recess 33. A resilient portion 35 extends from a first end wall bounding the opening 34 adjacent to the sidewall 39. The resilient portion 35 includes an extension portion 351 extending from and coplanar with the top wall 31, a connection portion 352 slantingly extending down from the distal end of the extension portion 351, and a cantilever 353 extending from a bottom end of the connection portion 352, away from and parallel to the extension portion 351. A protrusion 36 protrudes up from the cantilever 353. A top end of the protrusion 36 extends above the top wall 31. A wedge-shaped latch 37 extends up from the distal end of the cantilever 353. Two grooves 38 are defined in the top wall 31, at opposite sides of the opening 34. Two slide slots 381 are defined in the bottom wall 32, communicating with the corresponding grooves 38 and extending along the direction perpendicular to the sidewall 39. A pin 391 protrudes from the sidewall 39.

In assembly, a first end of the resilient member 40 is placed around the pole 26 and abuts against the stopping tab 25. The fixing member 30 is placed on the bottom plate 21. The hooking portion 24, the stopping tab 25, and the resilient member 40 are received in the recess 33. The limitation protrusions 28 are slidably accommodated in the corresponding slide slots 381. A second end of the resilient member 40 abuts against the end wall 331. Therefore, the fixing member is slidable relative to the bottom plate 21. The protrusion 36 is pressed down to deform the cantilever 353 downward.

The fixing member 30 is moved away from the first tabs 22, thus deforming the resilient member 40. The cantilever 353 moves below the hooking portion 24. The protrusion 36 is then released, and the cantilever 353 is self-restored to make the latch 37 engage in the hooking slot 27. Therefore, the fixing member 30 is fixed to the rack 20.

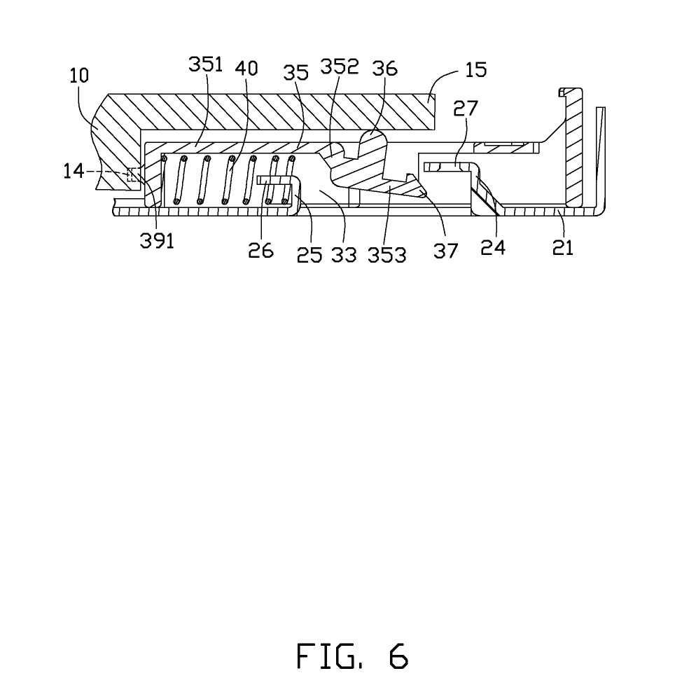

Referring to FIG. 6, to fix the ODD 10, the pins 23 engage in the corresponding holes 13. The ODD 10 is moved down. The plate 15 presses the protrusion 36 down to deform the cantilever 335 down. The latch 37 disengages from the hooking slot 27. The second sidewall 12 abuts against the second tab 29. The first sidewall 11 abuts against the first tabs 22. The resilient member 40 is self-restored, to allow the fixing member 30 to move towards the ODD 10. The pin 391 engages in the locking hole 14. Therefore, the ODD 10 is fixed to the rack 20.

To detach the ODD 10 from the rack 20, the fixing member 30 is moved towards the hooking portion 24, to allow the pin 391 to disengage from the locking hole 14. The resilient member 40 is deformed. The ODD 10 is moved up, to disengage the pins 23 from the corresponding holes 13. Therefore, the ODD 10 is disassembled from the rack 20.

It is believed that the present embodiments and their advantages will be understood from the foregoing description, and various changes may be made thereto without departing from the spirit and scope of the description or sacrificing all of their material advantages, the examples hereinbefore described merely being exemplary embodiments.

What is claimed is:

1. A fixing device for fixing a data storage device, the fixing device comprising:
a rack comprising a bottom plate to support the data storage device and two first tabs protruding up from the bottom plate to abut against a first side of the data storage device, two first pins respectively extending from the first tabs to engage in two corresponding holes defined in the first side of the data storage device;
a fixing member slidably attached to the bottom plate along a direction perpendicular to the first tabs, a second pin protruding from the fixing member; and
a resilient member resiliently sandwiched between the rack and the fixing member, to bias the fixing member to move towards the first tabs, thereby making the second pin engage in a locking hole defined in a second side of the data storage device opposite to the first side.

2. The fixing device of claim 1, wherein a stopping tab protrudes up from the bottom plate, the resilient member is sandwiched between the stopping tab and the fixing member.

3. The fixing device of claim 2, wherein the fixing member comprises a bottom wall, the bottom wall defines a recess, the recess comprises an end wall adjacent to the first tabs, the stopping tab and the resilient member are received in the recess, opposite ends of the resilient member respectively abut against the stopping tab and the end wall.

4. The fixing device of claim 3, wherein a pole extends towards the first tabs from a top of the stopping tab, the resilient member is placed around the pole.

5. The fixing device of claim 3, wherein two slide slots are defined in the bottom wall of the fixing member, at opposite sides of the recess, the slide slots extend along a direction perpendicular to the first tabs, two limitation protrusions protrude from the bottom plate to slidably accommodated in the corresponding slide slots.

6. The fixing device of claim 3, wherein a hooking portion defining a hooking slot extends from the bottom plate, the fixing member forms a latch, the latch is detachably engaged in the hooking slot.

7. The fixing device of claim 6, wherein the fixing member further comprises a top wall, an opening above the recess is defined in the top wall, a resilient portion extends from a first end wall bounding the opening adjacent to the first tabs, the latch extends up from a distal end of the resilient portion, the hooking portion is L-shaped and received in the recess, the hooking slot is defined in a top of the hooking portion.

8. The fixing device of claim 7, wherein a protrusion extends up from the resilient portion, a top of the protrusion extends above the top wall of the fixing member, a plate extends from an upper portion of the second side of the data storage device, to press the protrusion down.

9. The fixing device of claim 8, wherein the resilient portion comprises an extension portion extending from and coplanar with the top wall of the fixing member, a connection portion slantingly extending down from a distal end of the extension portion, and a cantilever extending from a bottom end of the connection portion away from the first tabs, the protrusion extends up from the cantilever, the latch extends up from a distal end of the cantilever.

10. The fixing device of claim 1, wherein a second tab protrudes from the bottom plate to abut against the second side of the data storage device.
